(19) United States
(12) Patent Application Publication
(10) Pub. No.: US 2026/0238167 A1
(43) Pub. Date: Aug. 13, 2026

(54) TECHNIQUES FOR MULTI-HEAD ADAPTIVE CONTROLLER WITH SHARED PARAMETERS

(71) Applicant: Apple Inc., Cupertino, CA (US)

(72) Inventors: Pedro Mirassol Tomé, Munich (DE); Benjamin Laemmle, Freising (DE)

(73) Assignee: Apple Inc., Cupertino, CA (US)

(21) Appl. No.: 19/051,573

(22) Filed: Feb. 12, 2025

(51) Int. Cl. H03F 1/32; H04B 1/525

(52) U.S. Cl. CPC H03F 1/3258; H04B 1/525; H03F 2200/451

(57) ABSTRACT

Techniques are described for a digital pre-distortion (DPD) and self-interference cancelation (SIC) actuator. The method can include receiving by at least one processor running a digital predistortion (DPD) model of a transceiver, a DPD input. The method can further include outputting, from the at least one processor and in response to the DPD input, a first DPD output of the DPD model. The method can further include causing the PA to generate a PA output based on the first DPD output. The method can further include updating the DPD model based on the DPD input, the DPD output and the PA output. The method can further include receiving, after the DPD model is updated, the DPD input by the at least one processor. The method can further include outputting, by the at least one processor, a second DPD output based on the DPD input.

### TECHNICAL FIELD

This application relates to the technical field of communication networks. In particular this application relates to multi-head adaptive controllers with shared parameters in said communication networks.

### BACKGROUND

Cellular communications can be defined in various standards to enable communications between a user equipment and a cellular network. For example, a long-term evolution (LTE) network, Fifth generation mobile network (5G), and Sixth Generation (6G) are wireless standards that aim to improve upon data transmission speed, reliability, availability, and more.

### BRIEF DESCRIPTION OF THE DRAWINGS

FIG. 1 is an illustration of an example communication system including a shared digital pre-distortion (DPD) and self-interference cancellation (SIC) actuator, according to one or mor embodiments.

FIG. 2 is an illustration of an example DPD and SIC actuator, according to one or more embodiments.

FIG. 3 is an illustration of an example comparison between independent DPD and SIC actuators and a joint DPD and SIC actuator, according to one or more embodiments.

FIG. 4 is an illustration of an example DPD training system, according to one or more embodiments.

FIG. 5 is an illustration of an example DPD training system, according to one or more embodiments.

FIG. 6 is an example process for determining DPD and SIC parameters, according to one or more embodiments.

FIG. 7 is an example process for training a DPD actuator, according to one or more embodiments.

FIG. 8 is an example process for training a DPD actuator, according to one or more embodiments.

FIG. 9 is an illustration of an example of a user equipment (UE), in accordance with some embodiments.

FIG. 10 is an illustration of an example of a network node, in accordance with some embodiments.

### DETAILED DESCRIPTION

A communication device can use a radio frequency (RF) transceiver for wireless communications (e.g., cellular 4G, 5G, 6G, WiFi, or other wireless communications). One technique in wireless communication is digital pre-distortion (DPD), which can include a signal processing technique for improving the efficiency and linearity of a transceiver's power amplifier (PA). The DPD can generally model the inverse transfer characteristics of an RF transmitter front-end that includes the PA. Furthermore, the PA is a critical component in the RF transmitter front-end, but can introduce a nonlinear distortion to the transmitted signal, especially when operating near its maximum power output. This distortion can degrade signal quality and cause interference in adjacent frequency channels. Another technique in wireless communications can include self-interference cancellation (SIC), which can include a signal processing technique used to mitigate or eliminate interference caused by a communication system's own transmitted signal when it interferes with its ability to receive signals. The SIC can generally model the forward transfer characteristics of a cascaded DPD and RF transmitter front-end. This can be relevant in a communication system that simultaneously transmits and receives signals on the same frequency (e.g., a full-duplex communication system).

One issue is that a conventional communication system can use an actuator with a machine learning model for DPD operations and another actuator with another machine learning model for SIC operations. Each of the actuators can include one or more of a set of kernels and/or basis functions, a set of neurons, a set of parameters, a set of coefficients, a set of weights, and a set of biases. Each of the actuators can generally implement functions that require a similar level of computational complexity, and this generally requires a similar number of kernels and parameters, and similar power consumption as well as area, and memory footprints.

In conventional systems, a first actuator can be implemented as a first controller that models DPD, whereas a second actuator can be implemented as a second, separate controller that models SIC. In contrast, the embodiments herein describe a single actuator that can generate multiple control signals (e.g., DPD control signals and SIC control signals) from a shared set of input signals and a shared set of kernels (e.g., basis functions). The control signals can be configured for controlling DPD parameters or SIC parameters. The embodiments herein describe techniques to permit full-duplex communication in devices, such as mobile handheld devices. The embodiments herein can enable full-duplex communications (in any cellular system including 4G, 5G, 6G) by introducing SIC functionality to a transceiver that already includes DPD functionality.

The embodiments herein can enable low-cost and power, area, and/or memory efficient implementation of DPD and SIC actuators. The embodiments herein provide several technical advantages over conventional communication techniques. For example, as described herein a single actuator can be used to generate control signals for both DPD operations and SIC operations. Therefore, the techniques herein can enable an approximately fifty percent reduction in the number of parameters used for determining the DPD operations and SIC operations of a communication device. Additionally, using a single actuator rather than multiple independent actuators can enable an approximately fifty percent improvement in the power consumption and area/memory footprint for determining DPD operations and SIC operations.

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrase “A or B” means (A), (B), or (A and B); and the phrase “based on A” means “based at least in part on A,” for example, it could be “based solely on A” or it could be “based in part on A.”

The following is a glossary of terms that may be used in this disclosure.

The term “circuitry” as used herein refers to, is part of, or includes hardware components such as an electronic circuit, a logic circuit, a processor (shared, dedicated, or group) or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable system-on-a-chip (SoC)), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” as used herein refers to, is part of, or includes circuitry capable of sequentially and automatically carrying out a sequence of arithmetic or logical operations, or recording, storing, or transferring digital data. The term “processor circuitry” may refer to an application processor, baseband processor, a central processing unit (CPU), a graphics processing unit, a single-core processor, a dual-core processor, a triple-core processor, a quad-core processor, or any other device capable of executing or otherwise operating computer-executable instructions, such as program code, software modules, or functional processes.

The term “user equipment” or “UE” as used herein refers to a device with radio communication capabilities and may describe a remote user of network resources in a communications network. The term “user equipment” or “UE” may be considered synonymous to, and may be referred to as, client, mobile, mobile device, mobile terminal, user terminal, mobile unit, mobile station, mobile user, subscriber, user, remote station, access agent, user agent, receiver, radio equipment, reconfigurable radio equipment, reconfigurable mobile device, etc. Furthermore, the term “user equipment” or “UE” may include any type of wireless/wired device or any computing device including a wireless communications interface.

The term “base station” as used herein refers to a device with radio communication capabilities, that is a network component of a communications network (or, more briefly, a network), and that may be configured as an access node in the communications network. A UE's access to the communications network may be managed at least in part by the base station, whereby the UE connects with the base station to access the communications network. Depending on the radio access technology (RAT), the base station can be referred to as a gNodeB (gNB), eNodeB (eNB), access point, etc.

The term “3GPP Access” refers to accesses (e.g., radio access technologies) that are specified by 3GPP standards. These accesses include, but are not limited to, GSM/GPRS, LTE, LTE-A, 5G NR, or 6G. In general, 3GPP access refers to various types of cellular access technologies.

The term “Non-3GPP Access” refers to any accesses (e.g., radio access technologies) that are not specified by 3GPP standards. These accesses include, but are not limited to, WiMAX, CDMA2000, Wi-Fi, WLAN, or fixed networks. Non-3GPP accesses may be split into two categories, “trusted” and “untrusted.” Trusted non-3GPP accesses can interact directly with an evolved packet core (EPC) or a 5G core (5GC), whereas untrusted non-3GPP accesses interwork with the EPC/5GC via a network entity, such as an Evolved Packet Data Gateway, a 5G NR gateway, or a 6G gateway. In general, non-3GPP access refers to various types on non-cellular access technologies.

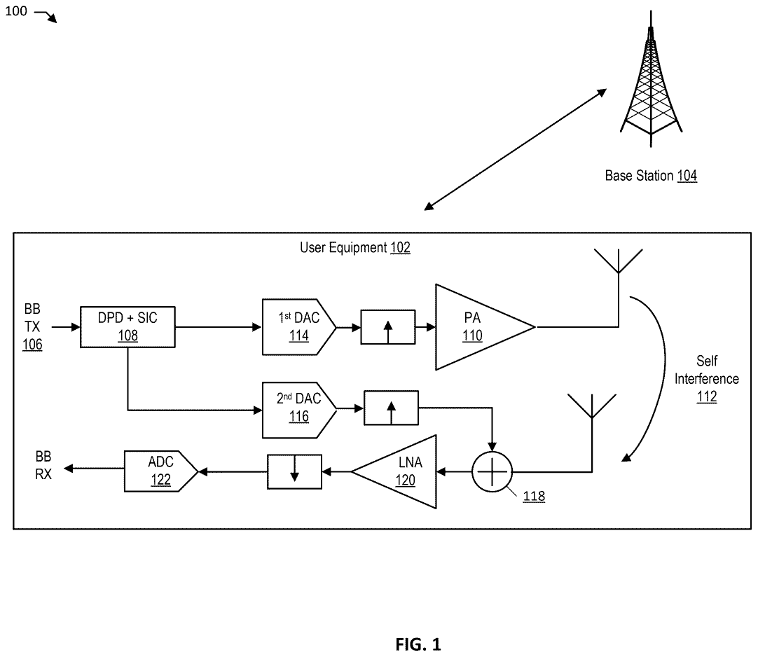

FIGS. 1, 2, and 3 are provided to describe a DPD and SIC actuator.

FIG. 1 is an illustration 100 of an example communication system including a shared DPD and SIC actuator, according to one or more embodiments. As illustrated, a user equipment (UE) 102 is in communication with a base station 104. The base station 104 can support various networks (e.g., 4G, 5G, and 6G or other networks) and support 3GPP access or non-3GPP access. The UE 102 can include circuitry (e.g., transceiver circuitry) for transmitting and receiving signals from the base station 104. For example, the UE 102 can receive a communication signal (e.g., baseband (BB) transmission (Tx) 106) that can be processed by the circuitry. The communication signal can be provided to a DPD and SIC actuator 108, which can include a neural network (e.g., convolutional neural network (CNN) deep neural network (DNN), artificial neural network (ANN), or other neural network). The neural network can include multiple input nodes, a shared set of hidden layers for the DPD and SIC, and multiple heads. Each head can be configured for a specific task. For example, the neural network can include one or more heads for outputting parameters for a DPD model. The neural network can also include one or more heads for outputting parameters for a SIC model. Generally, the DPD and SIC actuator 108 can be configured (e.g., the neural network can be trained) to model DPD and SIC and output related control signals to improve operations of the UE's 102 RF front-end.

The DPD and SIC actuator 108 can process exclusive and shared inputs for generating the DPD and SIC model parameters. For example, the DPD and SIC actuator 108 can process exclusive DPD inputs, shared inputs, and exclusive SIC inputs. The DPD and SIC actuator 108 can extract features for determining the DPD parameters from the exclusive DPD inputs. The DPD and SIC actuator 108 can extract features for determining the SIC parameters from the exclusive SIC inputs. The DPD and SIC actuator 108 can extract shared features to be used for determining the DPD parameters from the exclusive DPD inputs and from the shared features. For example, a set of output nodes of one or more of the heads can process a combination of features extracted from the DPD inputs and the shared inputs to determine the DPD parameters. Furthermore, another set of output nodes of one or more of the other heads can process a combination of features extracted from the SIC inputs and the shared inputs to determine the SIC parameters.

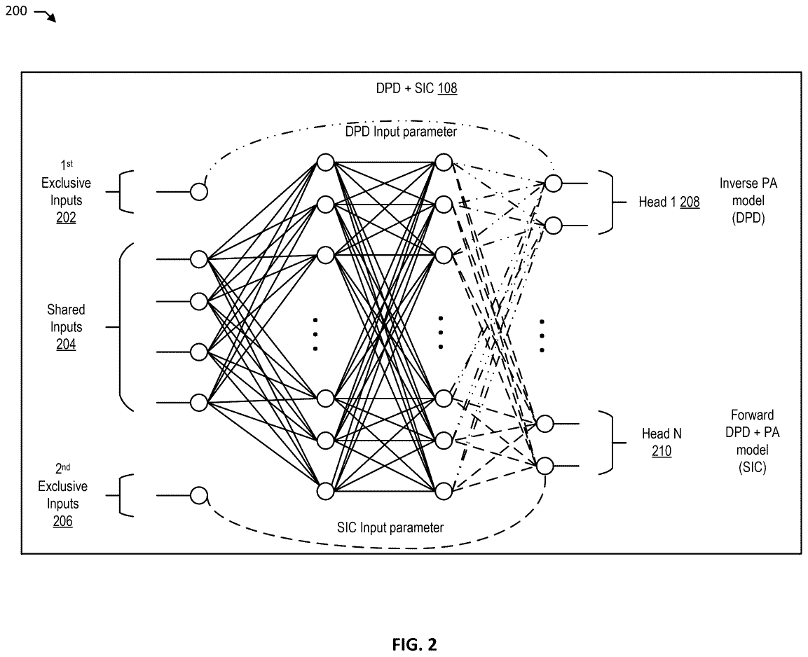

The DPD inputs, the SIC inputs, and the shared inputs can be processed by a single DPD and SIC actuator 108, which can reduce the footprint of the DPD and SIC processing in the UE 102. Furthermore, the UE's power consumption can be improved based on a single actuator processing for both DPD and SIC operations. The DPD and SIC actuator 108 can separately output DPD parameters (e.g., DPD model) and SIC parameters (e.g., SIC model). The DPD parameters can be for correcting or compensating for nonlinear distortions caused by a power amplifier (PA) 110. For example, the DPD model can be used to generate a pre-distorted signal by applying an inverse of the PA's nonlinear characteristics to the input signal. When this pre-distorted signal passes through the PA 110, the distortion introduced by the PA 110 can cancel out the predistortion, resulting in a clean, linear output signal. The SIC parameters can be used to characterize the transmitted signal, including any distortions it undergoes (e.g., nonlinearities, multipath effects, reflections from the environment, or other distortions). The characterization can include modeling the PA's nonlinear behavior, antenna coupling, and propagation effects. The SIC model can estimate the self-interference signal 112. This estimated interference can be subtracted from the received signal, leaving only the desired external signal. The DPD and SIC actuator 108 is described with more particularity with respect to FIG. 2.

The DPD and SIC actuator 108 can output the DPD parameters to a first digital to analog converter (DAC) 114, which processes a digital signal and outputs an analog signal. The analog signal can be further be upconverted to shift the frequency to a high frequency (e.g., from an intermediate frequency to a high frequency). The upconverted signal can be processed by the PA 110 that can increase the power of the signal to a desired output power level for pushing the signal out of an antenna.

As indicated above, one issue for full-duplex communication is that the UE 102 can experience self-interference 112 where a transmission signal can interfere with an incoming received signal. For example, a transmitted signal can typically be stronger than an incoming received signal causing interference for the incoming received signal. Therefore, the SIC parameters can be used to cancel out the self-interference effects.

The SIC parameters can be transmitted to a second DAC and the outputted analog signal can be upconverted. The upconverted analog signal can be transmitted to a mixer 118 that can add the signal to an incoming received signal that includes a self-interference signal 112. The mixer 118 can process the SIC parameters and the incoming signal to cancel out the self-interference signal 112. The clean signal can be transmitted to a low-noise amplifier (LNA) 120. The LNA 120 can be configured to increase the power of the received signal while minimizing the amount of noise that may be added as a result of this process. The signal outputted by the LNA 120 can be down-converted to reduce the frequency of the signal. For example, the frequency can be reduced to an intermediate frequency. The down-converted signal can be transmitted to an analog to digital converter (ADC) 122. The ADC 122 can process an analog signal and convert it to a digital signal. The digital signal can be transmitted for further downstream processing, including modeling the PA's output.

FIG. 2 is an illustration 200 of an example DPD and SIC actuator, according to one or more embodiments. As illustrated, the DPD and SIC actuator 108 can have a neural network architecture that includes an input layer, a hidden layer, and an output layer. The input layer can include nodes (illustrated as circles) that are configured for receiving exclusive inputs. For example, the DPD and SIC actuator 108 can include one or more input nodes for processing first exclusive inputs 202. The inputs can be static inputs, adaptive inputs, or both (e.g., static backbone parameters and adaptive head parameters). Static inputs can be inputs that are fixed and unchanging during the operation of the DPD and SIC actuator 108. For example, static inputs can include pre-defined values. Adaptive inputs can dynamically evolve during operation of the DPD and SIC actuator 108. For example, adaptive inputs can include real-time measurements, such as real-time channel state measurements. The DPD and SIC actuator 108 can include a shared backbone that can learn the latent representation of the system state (e.g., instantaneous front-end state) which can be simultaneously mapped to a DPD function (e.g., DPD kernel) a SIC function (e.g., SIC kernel) or other relevant function (e.g., envelope tracking kernel). For example, envelope tracking can include monitoring an envelope (e.g., amplitude variation) of the transmitted signal outputted by the PA 110 in real-time. The envelope can represent the instantaneous amplitude of the signal. Based on a detected envelope, the supply voltage to the PA 110 can be updated. The voltage supplied to the PA 110 can be made to closely track the signal's envelope, ensuring that the PA 110 operates with sufficient power to amplify the signal without causing distortion.

The interactions between each head of the DPD and SIC actuator 108 and the backbone during model training may reinforce the learned latent representation of the system state and provide some amount of regularization, thus improving the quality of each head's output and the ability to extrapolate to unseen data (e.g., the performance of the DPD and SIC actuator 108 may be greater than the sum of its parts, or greater than the performance of individual DPD and SIC actuators.

The first exclusive inputs 202 can be used for determining the DPD parameters that characterize the PA's nonlinear behavior. The first exclusive inputs 202 can include information to be used for determining the DPD parameters, but not the SIC parameters For example, the first exclusive inputs 202 can include PA nonlinearity information, such as how an amplitude of an input signal can affect an amplitude of an output PA signal. The first exclusive inputs 202 can include information related to how an amplitude of an input signal can affect a phase of an output PA signal. The first exclusive inputs 202 can include PA memory affects, including how past signals can affect a current PA output signal. The first exclusive inputs 202 can include PA operating information, such as temperature, voltage levels, current levels, and power levels and other information that can affect the operation of the PA 110. The first exclusive inputs 202 can include a PA feedback signal that indicates how the PA 110 has distorted an input signal. The first exclusive inputs 202 can further include adjacent channel power ratio (ACPR) information. The first exclusive inputs 202 can further include a Volterra series to model the nonlinearity of the PA's behavior. The first exclusive inputs 202 can include other appropriate information.

The shared inputs 204 can be inputs used by the DPD and SIC actuator 108 to determine both the DPD parameters and the SIC parameters. The shared inputs can include outputted signal information to be used as reference information. For the DPD parameters, the signal can be used to determine pre-distortion to compensate for the nonlinearities in the PA 110. For the SIC parameters, the signal can be used to determine an estimate for canceling self-interference 112 at the receiver. The shared inputs 204 can include signal envelope information. For the DPD parameters, the envelope information can be used to determine the nonlinearities and memory effects in the PA 110. For the SIC parameters, the envelope information can be used to model interference caused by power dynamics between an outputted signal and incoming received signal. The shared inputs 204 can include received signal information. For the DPD parameters, the received signal information can be used in a feedback loop to evaluate distortions introduced by the PA 110 and refine the predistortion transfer function. For the SIC parameters, the received signal information can be used as an input for signal interference cancellation. The shared inputs 204 can include other appropriate information.

The second exclusive inputs 206 can include information to be used for the SIC parameters, but not the DPD parameters. The second exclusive inputs 206 can include self-interference path characteristics information that indicate the characteristics of the self-interference path. For example, the second exclusive inputs 206 can include antenna coupling information, multipath effect information, channel state information, and feedback delay information. The second exclusive inputs 206 can include for example, composite self-interference signal information and residua interference information. This information can be used determine characteristics of the combination of the transmitted signal and the self-interference. This information can be used to determine the cancellation characteristics. The second exclusive inputs can include system information. For example, the second exclusive inputs 206 can include operating environment and system architecture information that can be used to determine that the environment of architecture contribute to the self-interference. The second exclusive inputs 206 can include other appropriate information.

As indicated above, the DPD and SIC actuator 108 can use shared kernels to generate the DPD parameters and the SIC parameters. Kernels can be functions used by the DPD and SIC actuator 108 to determine the DPD parameters or the SIC parameters. For example, the DPD and SIC actuator 108 can use a Volterra series kernel that can be used to determine a nonlinear behavior of RF components and interference effects for determining both DPD parameters and SIC parameters. The DPD and SIC actuator 108 can use a polynomial kernel for approximating the nonlinearity of the PA 110. The polynomial kernel can also be used to model and cancel the self-interference signal 112. The DPD and SIC actuator 108 can uses a basis function kernel (e.g., e.g., Fourier kernel, wavelet kernel or other basis function kernel). By using the same kernels for determining both DPD parameters and SIC parameters, the DPD and SIC actuator 108 can conserve memory space and consume less power than a DPD actuator and separate SIC actuator were using duplicate or similar kernels. The DPD and SIC actuator 108 can share other appropriate kernels.

The shared parameters and/or kernels can comprise an “oracle” sub-system that (1) can infer the state of the overall transmission system (or, e.g., the RF PA 110), and (2) can encode the system state as an embedding vector that can be mapped and/or drawn from to generate a multitude of control signals (e.g., via multiple heads). As illustrated, the DPD and SIC actuator 108 can include a multi-head neural network architecture. The DPD and SIC actuator 108 can include a first head 208 (e.g., Head 1) for outputting DPD parameters or a DPD model. The first head 208 can output pre-distorted signal parameters. These parameters can be used to counteract the nonlinearity and memory effects introduced by the PA 110. The pre-distorted signal parameters can be generated by the DPD and SIC actuator 108 using one or more kernels, (e.g., polynomial kernel, memory polynomial kernel, Volterra series-based kernel, or other kernel). The DPD and SIC actuator 108 can include a second head 210 (e.g., Head N) for outputting SIC parameters or a SIC model. The second head 210 can output a cancellation signal that includes an estimated version of the self-interference signal 112. This cancellation signal can be used by the mixer 118 to subtract the self-interference signal from the received signal to mitigate the interference.

As illustrated, the heads of the DPD and SIC actuator 108 can pass the first exclusive input 202 to a node of the first head 208. Therefore, the node can process information extracted from the first exclusive input 202 and information extracted from the shared inputs 204 to output one or more DPD parameters. For illustration purposes the information related to the DPD output is indicated by a dashed dot dot line. Additionally, the heads of the DPD and SIC actuator 108 can pass the second exclusive input 206 to a node of the second head 210. Therefore, the node can process information extracted from the second exclusive input 206 and information extracted from the shared inputs 204 to output one or more SIC parameters. For illustration purposes the information related to the SIC output is indicated by a dashed line. In this sense, the hidden layer nodes can process the shared inputs to generate information that can be used to determine either the DPD parameters or the SIC parameters. The DPD information is introduced at a node of the first head 208 and SIC information is introduced at a node of the second head 210 to output DPD or SIC specific parameters.

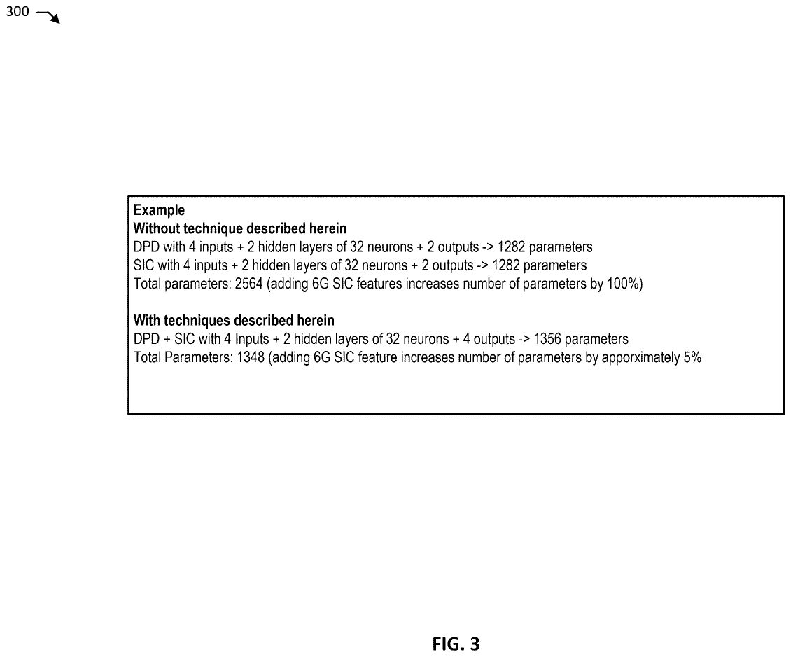

FIG. 3 is an illustration 300 of an example comparison between independent DPD and SIC actuators and a joint DPD and SIC actuator, according to one or more embodiments. As illustrated, for a UE that uses separate DPD and SIC actuators, the number of parameters for each of the DPD actuator and the SIC actuator is 1282 parameters, for a total of 2564. This increase can be due to adding a separate SIC actuator to circuitry that includes a DPD actuator, thereby increasing the number of parameters by 100%.

The embodiments herein describe techniques for a joint DPD and SIC actuator 108. As illustrated, for a UE that uses the DPD and SIC actuator 108, the number of parameters for the DPD and SIC actuator 108 is 1348 parameters. This can be due to adding a separate SIC actuator to circuitry that includes a DPD actuator increases the number of parameters by approximately 5% of 1,282 parameters (e.g., number of parameters for the standalone DPD actuator described above).

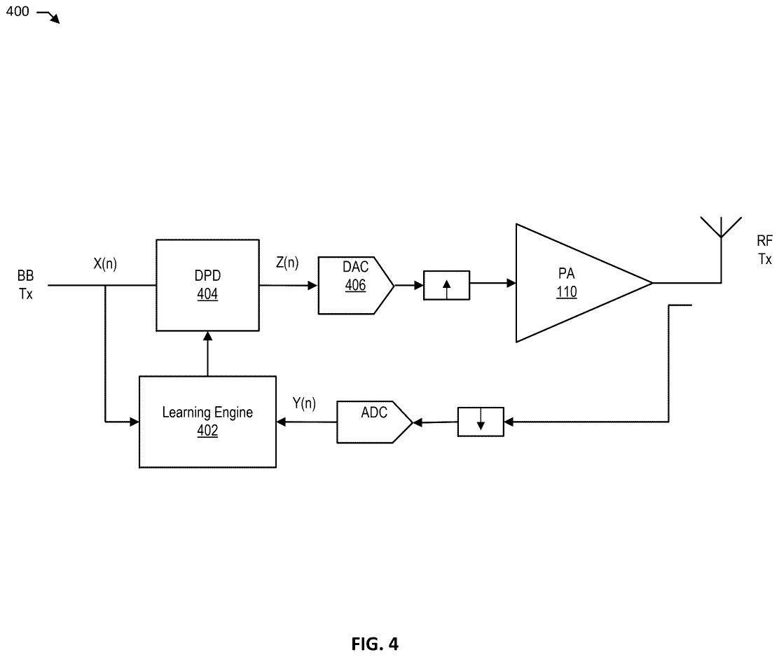

The embodiments herein further provide techniques for training a DPD model. FIG. 4 is provided to illustrate a first training technique.

The embodiments herein provide techniques for training a digital predistortion (DPD) model (e.g. the DPD portion of the DPD and SIC actuator 108) for generating DPD parameters. The DPD parameters can be used for linearizing the output of the PA 110 in a communication system is disclosed. The training process involves initializing the DPD model parameters, which may include coefficients of a polynomial, neural network weights, or basis functions designed to model both static and dynamic nonlinearities of the PA 110. The model parameters can be iteratively optimized using a loss function that minimizes the error between the pre-distorted PA output and the desired linear output. The optimization can employ gradient-based techniques to converge on a parameter set that compensates for the PA's distortions.

The identification and down-selection of the DPD kernels (e.g., basis functions) can be challenging and may require sophisticated methodologies and/or extensive manual work. These challenges can be aggravated by the highly dynamic operating conditions (e.g., band, channel, bandwidth, allocation, power, temperature, voltage standing wave ratio (VSWR)), device aging, and part-to-part variations in mass-market deployment of cellular transceivers for mobile communications devices. Training a neural network can require a priori knowledge of ideal DPD responses for a given set of input training signals (e.g., a full data set). The embodiments herein address the above references by providing techniques for self-supervised online incremental learning of a neural network-based DPD parameters without a priori knowledge of ideal DPD output responses. The embodiments herein can be fully applied to differentiable DPD models (including the more conventional Volterra series-based models) and also applied to all non-differentiable DPD models.

FIG. 4 is an illustration 400 of an example DPD training system, according to one or more embodiments. A learning engine (e.g., neural network training system) 402 can define a target (Z_{target}) for an output, Z(n), of the DPD model 404. The target can be a soft target in that the target can incrementally move the DPD model closer to an ideal output at each learning step. A learning step can be considered as passing an input through the DPD model 404, measuring an output of the PA, and comparing the output to a desired output. The learning step can further include using a loss function to determine the accuracy of the output, Z(n), and updating the weights of the model to reach Z_{target}. The DPD model 404 can be repeatedly trained via the learning step until the output Z(n) reaches an ideal state.

For example, the DPD model 404 can process an input, X(n) and generate an output Z(n). The output Z(n) can include one or more DPD parameters. The output Z(n) can be passed through a DAC 406 to convert the digital signal into an analog signal. The analog signal can be up-converted and passed to a PA 110 that can output a communication signal. The communication signal can be received and down-converted. The down-converted communication signal can be passed to an ADC 408 that can convert the analog signal into a digital signal. The ADC 408 can generate an output Y(n). The learning engine 402 can process Y(n) to determine whether Z(n) equals Z_{target}, where Z_{target} can be expressed as follows:

$${Z}_{target} ( n ) ≅ Z ( n ) - λ [ \frac{Y ( n )}{G} - X ( n ) ] , where G = \frac{E {‖ Y ‖}_{2}}{E {‖ X ‖}_{2}} ,$$

where λ can be a hyperparameter (e.g., learning rate) that is ≤1. Furthermore, Y can be assumed to be time-aligned with X.

The learning engine 402 can further use a loss function to determine the accuracy of the DPD model 404, where the loss function, L, can be expressed as follows:

$$L = \frac{{λ}^{2}}{N} {\sum }_{n = 0}^{N - 1} {[ \frac{Y ( n )}{G} - X ( n ) ]}^{2} ,$$

where N can be a number of samples.

The learning engine 402 can further use the loss function, L to determine a gradient, wherein the gradient can be expressed as follows:

$$\frac{d L}{d Z} = \frac{2 {λ}^{2}}{N} {\sum }_{n = 0}^{N - 1} [ \frac{Y ( n )}{G} - X ( n ) ] .$$

The learning engine 402 can incrementally update the DPD model's parameters and kernels based on the gradient. The loss function, C, can quantify how well the DPD model's prediction, Z(n) matches Z_{target}. The loss function can be based on the DPD model's weights, which are the parameters to be optimized. The learning engine 402 can determine a gradient, which can be a vector of partial derivatives of the loss function with respect to each weight in the DPD model 404. The gradient can indicate the direction and rate of the steepest increase in the loss function, L. By moving in the opposite direction of the gradient, the DPD model can reduce the loss. Once the gradient is determined, the learning engine 402 can update the weights of the DPD model. The model incrementally updates the weights at each learning step until Z(n) equals Z_{target}. For example, the learning engine 402 can apply a gradient descent technique to iteratively update the DPD model's parameters to minimize the loss function, L.

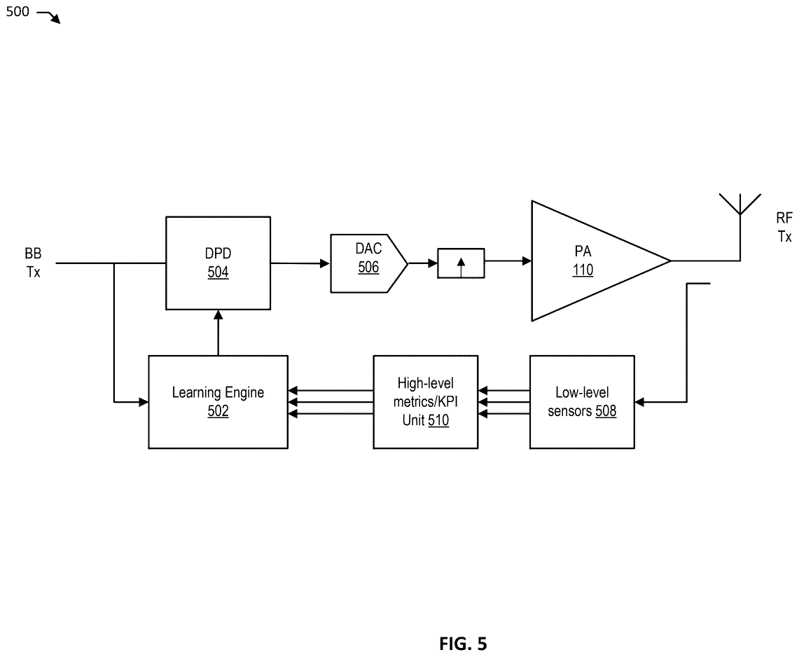

FIG. 5 is provided to illustrate a second training technique.

The herein embodiments describe techniques for optimizing a DPD model using a reinforcement learning (RL). RL can be a learning technique where an agent interacts with a DPD model to achieve a predefined objective (e.g., desired DPD parameters) by learning a policy through trial-and-error interactions. In particular, the DPD model can receive feedback in the form of scalar rewards, which serve as a quantitative measure of the DPD model's performance relative to the objective. The DPD's behavior can be governed by a policy, which can define the probability distribution over actions (e.g., DPD parameter determinations) given a state. The learning engine can optimize this policy by maximizing the expected cumulative reward.

Conventional DPD model training can require large training datasets composed of reference input signals and corresponding measured PA output signals. Obtaining these datasets can incur a significant burden, as it generally requires a dedicated wideband feedback receiver sub-system with stringent linearity requirements to measure and sample the PA output signal waveform. It can also require a dedicated memory to store measured and reference signals. Additionally, it can require the alignment of measured PA output signals against reference input signals with respect to time, power, and phase, which can require a high computational effort.

The embodiments herein address the above referenced by providing a learning engine that can learn from high-level metrics and/or key performance indicators (KPIs) (e.g. adjacent channel leakage ratio (ACLR), error vector magnitude (EVM)) instead of sampled input/output waveforms.

For example, a learning engine 502 may be pre-trained on a very large set of PA transfer characteristics and operating conditions. The learning engine 502 can be deployed without requiring any further training, enabling a generalized zero-shot adaptation of DPD parameters solely from high-level KPIs. The DPD model 504 can process an input and generate an output. The output can include one or more DPD parameters. The output can be passed through a DAC 506 to convert the digital signal into an analog signal. The analog signal can be up-converted and passed to a PA 110 that can output a communication signal. The communication signal can be received and processed by low-level sensors 508 (e.g., power sensors). A high-level metrics/KPI unit 510 can determine one or more metrics/KPIs from the signals collected by the low-level sensors 508. For example, the high-level metrics/KPI unit 510 can determine an ACLR. The ACLR can be a measurement of the amount of signal power that leaks from a transmission channel into an adjacent frequency channel. The high-level metrics/KPI unit 510 can also measure an EVM. The EVM can be a measure of the difference between a desired transmitted signal and the actual signal that is received. The EVM can further be a measure of the level of distortion and imperfections attributable to the PA 110.

The learning engine 502 can use the metrics/KPIs to determine a state of the communication system (e.g., whether the DPD model is outputting parameters to reduce or eliminate the distortions (e.g., non-linearity) introduced by the PA 110. If the DPD model 504 is generating parameters that reduce or eliminate the distortions, the learning engine 502 can issue a reward. If, however, the DPD model 504 is not generating parameters that reduce or eliminate the distortions, the learning engine 502 can issue a penalty. The learning engine 502 can then update the DPD model's policy to cause a determination of DPD parameters that maximize an expected reward. For example, the learning engine 502 can use a policy gradient method, a value gradient method, or an actor-critic method. For an actor-critic method, the learning engine (critic) 502 can evaluate DPD parameters determined by the DPD model (actor) 504. The DPD model 504 can update the policy parameters using the feedback from the learning engine 502. The learning engine can update the value function parameters. The value function can be the function that the DPD model 504 uses to determine the DPD parameters in order to maximize a reward. This process can be repeated until the policy converges to an optimal or near-optimal policy (e.g., the DPD model 504 determines DPD parameters to reduce or eliminate the distortions created by the PA 110).

Each of the above described training techniques can be offline training techniques where the model is trained before being deployed into the market. The technique can also be an online technique, in which the model is trained after deployment. For example, the DPD model can be trained using live data as a user is using their user equipment 102.

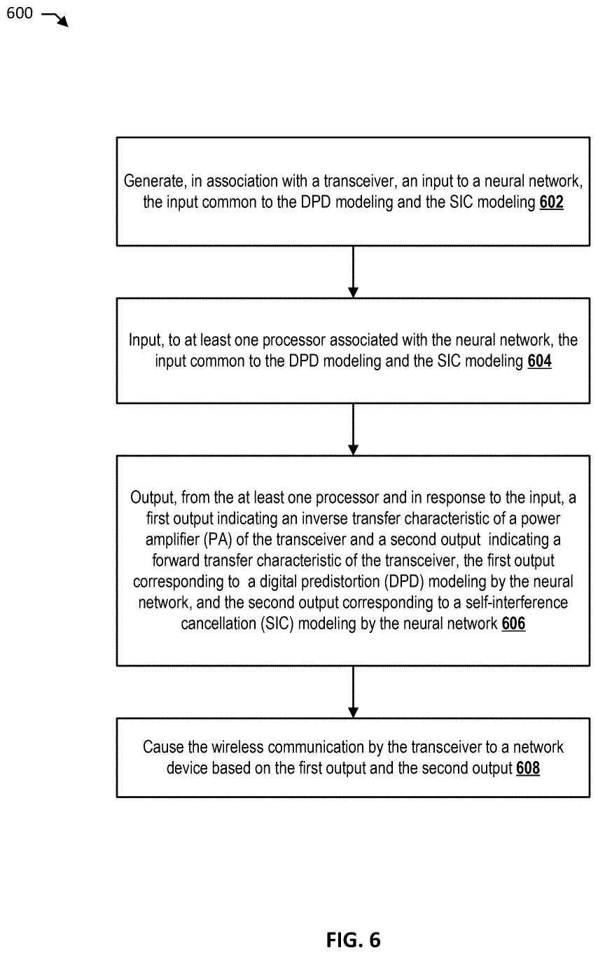

FIG. 6 is an example process 600 for determining DPD and SIC parameters, according to one or more embodiments. At 602, the process 600 can include an apparatus (e.g., circuitry configured to use the DPD and SIC actuator 108) generating, in association with a transceiver, an input to a neural network, the input common to a DPD modeling and a SIC modeling. The apparatus can be configured to encode a system state of the transceiver as a vector. The apparatus can further be configured to map the system state to a DPD function or a SIC function. An output of the apparatus can be based on the mapping.

At 604, the process 600 can include the apparatus inputting, to at least one processor associated with the neural network, the input common to the DPD modeling and the SIC modeling.

At 606, the process can include the apparatus outputting, from the at least one processor and in response to the input, a first output indicating an inverse transfer characteristic of a power amplifier (PA) of the transceiver and a second output indicating a forward transfer characteristic of the transceiver, the first output corresponding to the DPD modeling by the neural network, and the second output corresponding to the SIC modeling by the neural network. For example, the apparatus can process the input and an exclusive DPD input (e.g., PA nonlinearity information or other DPD information) at an output node. The exclusive DPD input can be exclusive to the DPD modeling. The DPD output can be based on processing the first input with the exclusive DPD input at the output node. The input can be processed by a first input node common for DPD modeling and SIC modeling. The exclusive DPD input can be processed by a second input node exclusive for DPD modeling. For example, the apparatus can process the first input and an exclusive SIC input (e.g., self-interference path characteristics information or other SIC information) at an output node, the exclusive SIC input exclusive to the SIC modeling. The SIC output can be based on processing the first input with the exclusive SIC input at the output node (e.g., node of the second head 210). The input can be processed by a first input node common for DPD modeling and SIC modeling. The exclusive SIC input can be processed by a second input node exclusive for SIC modeling.

As illustrated in FIG. 2, a DPD input parameter can be passed directly from a first input node to a node of the first head 208 of the neural network. The DPD parameter outputted at the first head 208 can be based on passing the DPD parameter directly from the first input node to a node of the first head of the neural network. As further illustrated in FIG. 2, a SIC input parameter can be passed directly from a first input node to a node of the second head 210. The SIC parameter outputted at the second head 210 can be based on passing the SIC parameter directly from the first input node to a node of the second head 210 of the neural network.

At 608, the process 600 can include the apparatus causing the wireless communication by the transceiver to a network device based on the first output and the second output. For example, the apparatus can generate control instructions for a power amplifier based on the DPD model, wherein the control instructions are generated based on inverse transfer characteristics of a RF front-end as determined by the DPD model. The apparatus can further generate control instructions for an LNA 120 based on the SIC model. The control instructions can be generated based on forward transfer characteristics of a DPD and RF front-end as determined by the SIC model.

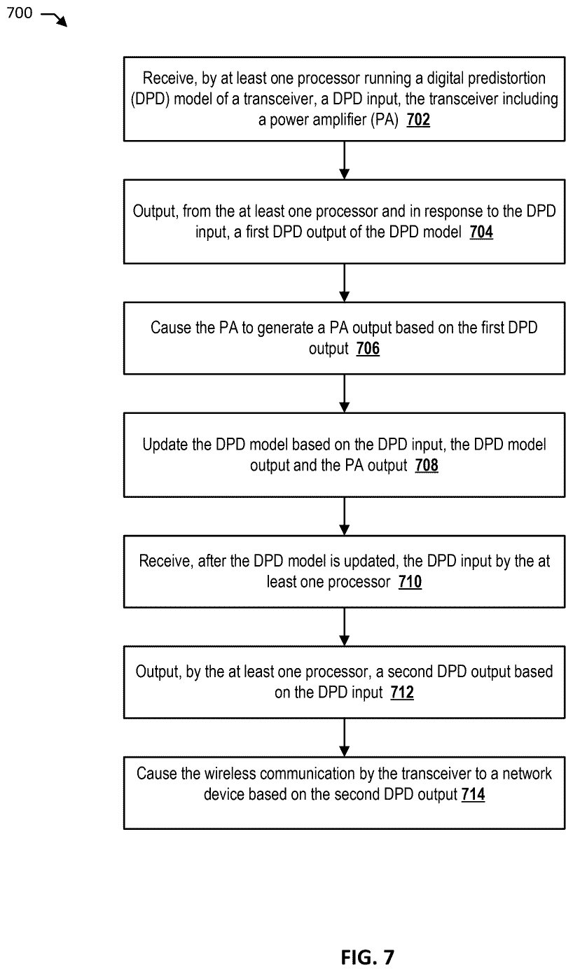

FIG. 7 is an example process 700 for training a DPD actuator, according to one or more embodiments. At 702, the process can include an apparatus (e.g., (e.g., circuitry configured to use the DPD and SIC actuator 108) receiving by at least one processor running a DPD model of a transceiver, a DPD input, the transceiver including a PA.

At 704, the process 700 can include the apparatus outputting, from the at least one processor and in response to the DPD input, a first DPD output of the DPD model.

At 706, the process 700 can include the apparatus causing the PA to generate a PA output based on the first DPD output. The apparatus can determine that the DPD input is time-aligned with the first PA output, wherein the communication signal is further based on determining that the model input parameter is time-aligned with the first PA output parameter. In other instances, the apparatus can determine that the DPD input is phase-aligned with the PA output.

At 708, the process 700 can include updating the DPD model based on the DPD input, the DPD model output and the PA output. For example, the apparatus can determine a target DPD output (e.g., Z_{target}) based on a previous DPD output (e.g., Z(n−1), determined prior to the DPD output. The apparatus can determine a loss function based on the target DPD output. The apparatus can further determine a gradient of the loss function. The DPD model (e.g., a model weight) can be updated based on a self-supervised DPD training algorithm that uses the gradient. Updating the DPD model can incrementally update the first DPD output toward a target DPD output.

At 710, the process 700 can include the apparatus receiving, after the DPD model is updated, the DPD input by the at least one processor. At 712, the process 712 can include the apparatus outputting, by the at least one processor, a second DPD output based on the DPD input.

At 714, the process 700 can include the apparatus causing the wireless communication by the transceiver to a network device based on the second DPD output. For example, the apparatus can generate control instructions for a power amplifier based on the DPD model, wherein the control instructions are generated based on inverse transfer characteristics of a RF front-end as determined by the DPD model.

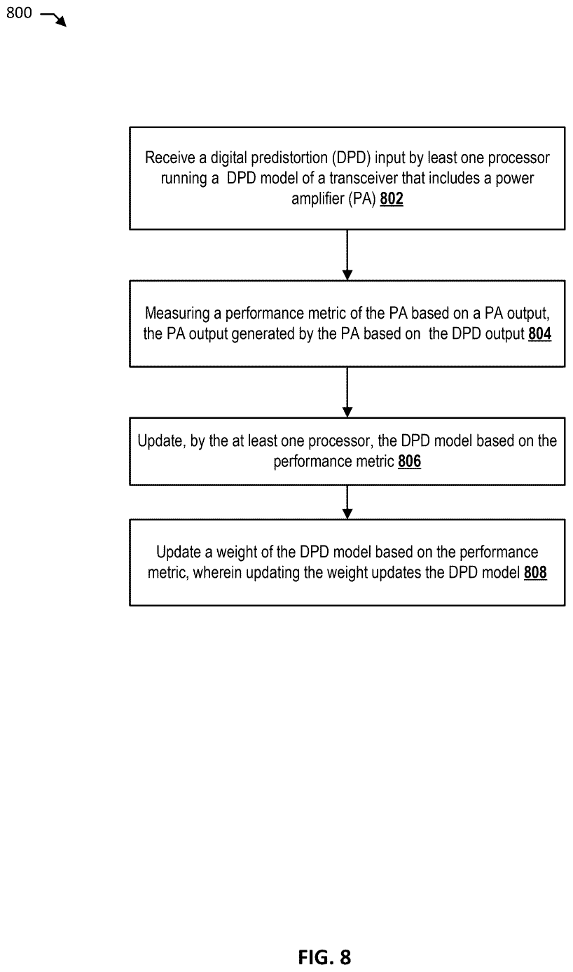

FIG. 8 is an example process 800 for training a DPD actuator, according to one or more embodiments. At 802, the process 800 can include an apparatus (e.g., (e.g., circuitry configured to use the DPD and SIC actuator 108) receiving, by the PA, a DPD output of the DPD model, the DPD output generated by the at least one processor in response to the DPD input. The DPD model can include a machine learning model.

At 804, the process 800 can include the apparatus measuring a performance metric (e.g., KPI) of the PA based on a PA output, the PA output generated by the PA based on the DPD output. For example, the performance metric can include an ACLR The learning engine can employ one or more sensors (e.g., low-level sensors 508) and measuring a first center frequency of a first channel of the output. The sensors can further measure a second center frequency of a second channel of the output. The second channel can be adjacent to the first channel. The learning engine (e.g., via the high-level metrics/KPI unit 510) can determine the ACLR based on measuring the first channel and the second channel. The communication signal is further based on the ACLR. In some instances, the ACLR is measured by multiple sensors. In other instances, the ACLR is measured by a single sensor. For example, the learning engine can set a sensor center frequency to correspond to the first center frequency. The first center frequency can be measured based on setting the sensor center frequency. The learning engine can then update the sensor center frequency to correspond to the second center frequency. The second center frequency can be measured based on updating the sensor center frequency.

In another example, the performance metric can include an EVM. The learning engine can (e.g., via the low-level sensors 508 and the high-level metrics/KPI unit 510) measure a distortion of a channel of the output. The EVM can based on the distortion, and the communication signal can further be based on the EVM.

At 806, the process 800 can include the apparatus updating, by the at least one processor, the DPD model based on the performance metric. For example, the apparatus can determine, based on a reinforcement learning technique, whether the performance metric corresponds to a reward or a penalty. The apparatus can then update, via a technique (e.g., deterministic policy gradient technique, stochastic gradient technique, value-based technique, model-based technique, or other appropriate technique) and whether the performance metric corresponds to the reward or the penalty, a policy of the DPD model, where updating the weight is further based on updating the policy. The reinforcement learning technique can apply, for example, an actor-critic architecture. An actor model can cause the PA to generate the output. A critic model determines whether the performance metric corresponds to the reward or the penalty. The weight of the model is updated based on the actor-critic architecture. It should be appreciated that the reinforcement learning technique can be used with different architectures. For example, the reinforcement learning technique can be used with different architectures for training a DPD model from various performance metrics (e.g., high-level KPIs).

At 810, the process 800 can include the apparatus causing the transceiver to output the wireless communication to a network device based on the updated DPD model. For example, the apparatus can generate control instructions for a power amplifier based on the DPD model, wherein the control instructions are generated based on inverse transfer characteristics of a RF front-end as determined by the DPD model.

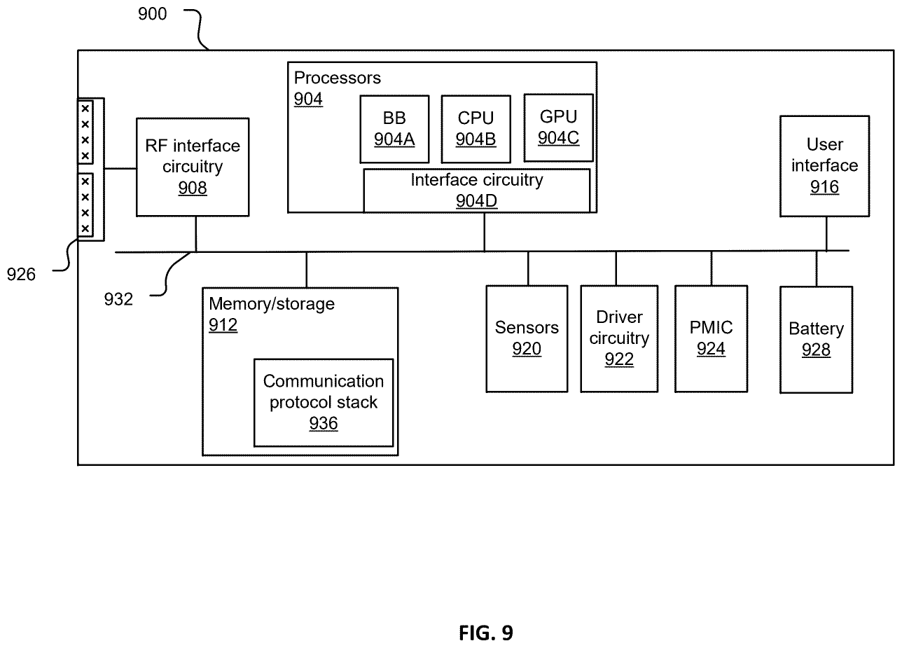

FIG. 9 illustrates a UE 900, in accordance with some embodiments. The UE 900 may be similar to and substantially interchangeable with a UE 102 of FIG. 1.

The processors 904 may include processor circuitry such as, for example, baseband processor circuitry (BB) 904A, central processor unit circuitry (CPU) 904B, and graphics processor unit circuitry (GPU) 904C. The processors 904 may include any type of circuitry or processor circuitry that executes or otherwise operates computer-executable instructions, such as program code, software modules, or functional processes from memory/storage 912 to cause the UE 900 to perform delay-adaptive operations as described herein. The processors 904 may also include interface circuitry 904D to communicatively couple the processor circuitry with one or more other components of the UE 900.

In some embodiments, the baseband processor circuitry 904A may access a communication protocol stack 936 in the memory/storage 912 to communicate over a 3GPP compatible network. In general, the baseband processor circuitry 904A may access the communication protocol stack 936 to: perform user plane functions at a PHY layer, MAC layer, RLC layer, PDCP layer, SDAP layer, and PDU layer; and perform control plane functions at a PHY layer, MAC layer, RLC layer, PDCP layer, RRC layer, and a NAS layer. In some embodiments, the PHY layer operations may additionally/alternatively be performed by the components of the RF interface circuitry 908.

The baseband processor circuitry 904A may generate or process baseband signals or waveforms that carry information in 3GPP-compatible networks. In some embodiments, the waveforms for NR may be based on cyclic prefix OFDM (CP-OFDM) in the uplink or downlink, and discrete Fourier transform spread OFDM (DFT-S-OFDM) in the uplink.

The memory/storage 912 may include one or more non-transitory, computer-readable media that includes instructions (for example, communication protocol stack 936) that may be executed by one or more of the processors 904 to cause the UE 900 to perform various delay-adaptive operations described herein.

The memory/storage 912 includes any type of volatile or non-volatile memory that may be distributed throughout the UE 900. In some embodiments, some of the memory/storage 912 may be located on the processors 904 themselves (for example, memory/storage 912 may be part of a chipset that corresponds to the baseband processor circuitry 904A), while other memory/storage 912 is external to the processors 904 but accessible thereto via a memory interface. The memory/storage 912 may include any suitable volatile or non-volatile memory such as, but not limited to, dynamic random access memory (DRAM), static random access memory (SRAM), erasable programmable read only memory (EPROM), electrically erasable programmable read only memory (EEPROM), Flash memory, solid-state memory, or any other type of memory device technology.

The RF interface circuitry 908 may include transceiver circuitry and a radio frequency front module (RFEM) that allows the UE 900 to communicate with other devices over a radio access network. The RF interface circuitry 908 may include various elements arranged in transmit or receive paths. These elements may include, for example, switches, mixers, amplifiers, filters, synthesizer circuitry, and control circuitry.

In the receive path, the RFEM may receive a radiated signal from an air interface via antenna 926 and proceed to filter and amplify (with a low-noise amplifier) the signal. The signal may be provided to a receiver of the transceiver that down-converts the RF signal into a baseband signal that is provided to the baseband processor of the processors 904.

In the transmit path, the transmitter of the transceiver up-converts the baseband signal received from the baseband processor and provides the RF signal to the RFEM. The RFEM may amplify the RF signal through a power amplifier prior to the signal being radiated across the air interface via the antenna 926.

In various embodiments, the RF interface circuitry 908 may be configured to transmit/receive signals in a manner compatible with NR access technologies.

The antenna 926 may include antenna elements to convert electrical signals into radio waves to travel through the air and to convert received radio waves into electrical signals. The antenna elements may be arranged into one or more antenna panels. The antenna 926 may have antenna panels that are omnidirectional, directional, or a combination thereof to enable beamforming and multiple input, multiple output communications. The antenna 926 may include microstrip antennas, printed antennas fabricated on the surface of one or more printed circuit boards, patch antennas, or phased array antennas. The antenna 926 may have one or more panels designed for specific frequency bands including bands in FR1 or FR2.

The user interface 916 includes various input/output (I/O) devices designed to enable user interaction with the UE 900. The user interface 916 includes input device circuitry and output device circuitry. Input device circuitry includes any physical or virtual means for accepting an input including, inter alia, one or more physical or virtual buttons (for example, a reset button), a physical keyboard, keypad, mouse, touchpad, touchscreen, microphones, scanner, headset, or the like. The output device circuitry includes any physical or virtual means for showing information or otherwise conveying information, such as sensor readings, actuator position(s), or other like information. Output device circuitry may include any number or combinations of audio or visual display, including, inter alia, one or more simple visual outputs/indicators (for example, binary status indicators such as light emitting diodes (LEDs) and multi-character visual outputs, or more complex outputs such as display devices or touchscreens (for example, liquid crystal displays (LCDs), LED displays, quantum dot displays, and projectors), with the output of characters, graphics, multimedia objects, and the like being generated or produced from the operation of the UE 900.

The sensors 920 may include devices, modules, or subsystems whose purpose is to detect events or changes in their environment and send the information (sensor data) about the detected events to some other device, module, or subsystem. Examples of such sensors include inertia measurement units comprising accelerometers, gyroscopes, or magnetometers; microelectromechanical systems or nanoelectromechanical systems comprising 3-axis accelerometers, 3-axis gyroscopes, or magnetometers; level sensors; flow sensors; temperature sensors (for example, thermistors); pressure sensors; barometric pressure sensors; gravimeters; altimeters; image capture devices (for example, cameras or lensless apertures); light detection and ranging sensors; proximity sensors (for example, infrared radiation detector and the like); depth sensors; ambient light sensors; ultrasonic transceivers; and microphones or other like audio capture devices.

The driver circuitry 922 may include software and hardware elements that operate to control particular devices that are embedded in the UE 900, attached to the UE 900, or otherwise communicatively coupled with the UE 900. The driver circuitry 922 may include individual drivers allowing other components to interact with or control various input/output (I/O) devices that may be present within, or connected to, the UE 900. For example, driver circuitry 922 may include a display driver to control and allow access to a display device, a touchscreen driver to control and allow access to a touchscreen interface, sensor drivers to obtain sensor readings of sensors 920 and control and allow access to sensors 920, drivers to obtain actuator positions of electro-mechanic components or control and allow access to the electro-mechanic components, a camera driver to control and allow access to an embedded image capture device, audio drivers to control and allow access to one or more audio devices.

The PMIC 924 may manage power provided to various components of the UE 900. In particular, with respect to the processors 904, the PMIC 924 may control power-source selection, voltage scaling, battery charging, or DC-to-DC conversion.

A battery 928 may power the UE 900, although in some examples the UE 900 may be mounted deployed in a fixed location and may have a power supply coupled to an electrical grid. The battery 928 may be a lithium ion battery, a metal-air battery, such as a zinc-air battery, an aluminum-air battery, a lithium-air battery, and the like. In some implementations, such as in vehicle-based applications, the battery 928 may be a typical lead-acid automotive battery.

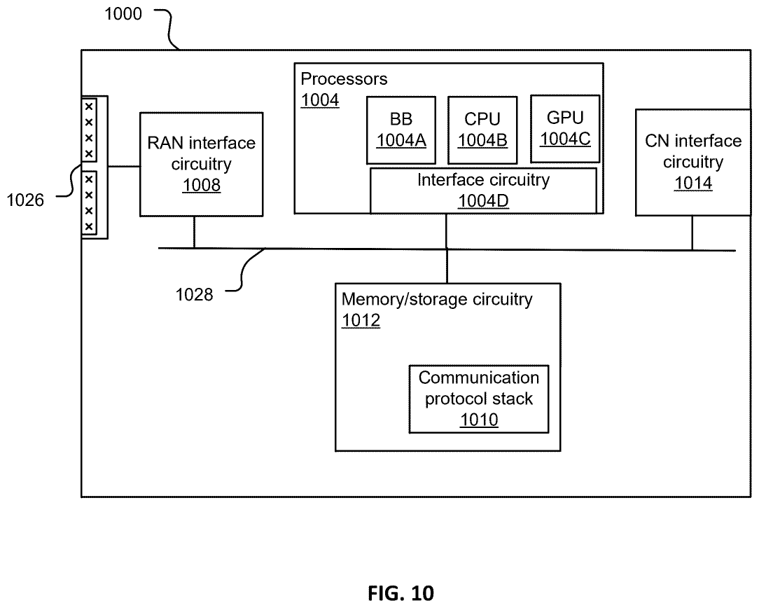

FIG. 10 illustrates a network device 1000 in accordance with some embodiments. The network device 1000 may be similar to and substantially interchangeable with base station 104 or a device of the core network or an external data network.

The network device 1000 may include processors 1004, RF interface circuitry 1008 (if implemented as a base station), core network (CN) interface circuitry 1014, memory/storage circuitry 1012, and antenna structure 1026.

The components of the network device 1000 may be coupled with various other components over one or more interconnects 1028.

The processors 1004, RF interface circuitry 1008, memory/storage circuitry 1012 (including communication protocol stack 1010), antenna structure 1026, and interconnects 1028 may be similar to like-named elements shown and described with respect to FIG. 9.

The processors 1004 may include processor circuitry such as, for example, baseband processor circuitry (BB) 1004A, central processor unit circuitry (CPU) 1004B, and graphics processor unit circuitry (GPU) 1004C. The processors 1004 may include any type of circuitry or processor circuitry that executes or otherwise operates computer-executable instructions, such as program code, software modules, or functional processes from memory/storage circuitry 1012 to cause the UE 1000 to perform delay-adaptive operations as described herein. The processors 1004 may also include interface circuitry 1004D to communicatively couple the processor circuitry with one or more other components of the network device 1000.

The CN interface circuitry 1014 may provide connectivity to a core network, for example, a 5th Generation Core network (5GC) using a 5GC-compatible network interface protocol such as carrier Ethernet protocols, or some other suitable protocol. Network connectivity may be provided to/from the network device 1000 via a fiber optic or wireless backhaul. The CN interface circuitry 1014 may include one or more dedicated processors or FPGAs to communicate using one or more of the aforementioned protocols. In some implementations, the CN interface circuitry 1014 may include multiple controllers to provide connectivity to other networks using the same or different protocols.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

For one or more embodiments, at least one of the components set forth in one or more of the preceding figures may be configured to perform one or more operations, techniques, processes, or methods as set forth in the example section below. For example, the baseband circuitry as described above in connection with one or more of the preceding figures may be configured to operate in accordance with one or more of the examples set forth below. For another example, circuitry associated with a UE, base station, or network element as described above in connection with one or more of the preceding figures may be configured to operate in accordance with one or more of the examples set forth below in the example section.

### EXAMPLES

In the following sections, further example embodiments are provided.

Example 1 can include a method for wireless communication comprising: receiving by at least one processor running a digital predistortion (DPD) model of a transceiver, a DPD input, the transceiver including a power amplifier (PA); outputting, from the at least one processor and in response to the DPD input, a first DPD output of the DPD model; causing the PA to generate a PA output based on the first DPD output; updating the DPD model based on the DPD input, the DPD output and the PA output; receiving, after the DPD model is updated, the DPD input by the at least one processor; outputting, by the at least one processor, a second DPD output based on the DPD input; and causing the wireless communication by the transceiver to a network device based on the second DPD output.

Example 2 can include the method of example 1, wherein the method further comprises: determining a target DPD output based on a third DPD output, the third DPD output determined prior to the first DPD output; and determining a loss function based on the target DPD output, wherein the wireless communication is based on the loss function.

Example 3 can include the method of any of examples 1 or 2, wherein the method further comprises: determining a loss function based on the DPD input; and determining a gradient of the loss function, wherein the DPD model is updated based on a self-supervised DPD training algorithm that uses the gradient.

Example 4 can include the method of any of examples 1-3, wherein updating the DPD model incrementally updates the first DPD output toward a target DPD output.

Example 5 can include the method of any of examples 1-4, wherein the method further comprises: determining that the DPD input is time-aligned with the PA output, wherein the wireless communication is further based on determining that the DPD input is time-aligned with the PA output.

Example 6 can include the method of any of examples 1-5, wherein the method further comprises: converting the first DPD output from a digital signal to an analog signal; and up-converting the analog signal, wherein the wireless communication is further based on up-converting the analog signal.

Example 7 can include the method of any of examples 1-6, wherein the PA output is a first PA output, and wherein the method further comprises: converting a second PA output from an analog signal to a digital signal; and down-converting the digital signal, wherein the first PA output is based on down-converting the digital signal.

Example 8 can include an apparatus comprising processor circuitry configured to perform any of the steps of example 1-7.

Example 9 can include one or more non-transitory, computer-readable media comprising a sequence of instructions that, when executed, cause processor circuitry to perform any of the steps of examples 1-7.

Example 10 can include an apparatus comprising: processor circuitry configured to: receive by at least one processor running a digital predistortion (DPD) model of a transceiver, a DPD input, the transceiver including a power amplifier (PA); output, from the at least one processor and in response to the DPD input, a first DPD output of the DPD model; cause the PA to generate a PA output based on the first DPD output; update the DPD model based on the DPD input, the DPD output and the PA output; receive, after the DPD model is updated, the DPD input by the at least one processor; output, by the at least one processor, a second DPD output based on the DPD input; and cause wireless communication by the transceiver to a network device based on the second DPD output.

Example 11 can include the apparatus of example 10, wherein the processor circuitry is further configured to: determine a target DPD output based on a third DPD output, the third DPD output determined prior to the first DPD output; and determine a loss function based on the target DPD output, wherein the wireless communication is based on the loss function.

Example 12 can include the apparatus of any of examples 10 or 11, wherein the processor circuitry is further configured to: determine a loss function based on the DPD input; and determine a gradient of the loss function, wherein the DPD model is updated based on a self-supervised DPD training algorithm that uses the gradient.

Example 13 can include the apparatus of any of examples 10-12, wherein updating the DPD model incrementally updates the first DPD output toward a target DPD output.

Example 14 can include the apparatus of any of examples 10-13, wherein the processor circuitry is further configured to: determine that the DPD input is time-aligned with the PA output, wherein the wireless communication is further based on determining that the DPD input is time-aligned with the PA output.

Example 15 can include the apparatus of any of examples 10-14, wherein the processor circuitry is further configured to: convert the first DPD output from a digital signal to an analog signal; and up-convert the analog signal, wherein the wireless communication is further based on up-converting the analog signal.

Example 16 can include the apparatus of any of examples 10-15, wherein the PA output is a first PA output, and wherein the processor circuitry is further configured to: convert a second PA output from an analog signal to a digital signal; and down-converting the digital signal, wherein the first PA output is based on down-converting the digital signal.

Example 17 can include a method for performing any of the steps of examples 10-16.

Example 18 can include one or more non-transitory, computer-readable media comprising a sequence of instructions that, when executed, cause processor circuitry to perform any of the steps of examples 10-16.

Example 19 can include one or more non-transitory, computer-readable media comprising a sequence of instructions that, when executed, cause processor circuitry to: receive by at least one processor running a digital predistortion (DPD) model of a transceiver, a DPD input, the transceiver including a power amplifier (PA); output, from the at least one processor and in response to the DPD input, a first DPD output of the DPD model; cause the PA to generate a PA output based on the first DPD output; update the DPD model based on the DPD input, the DPD output and the PA output; receive, after the DPD model is updated, the DPD input by the at least one processor; output, by the at least one processor, a second DPD output based on the DPD input; and cause wireless communication by the transceiver to a network device based on the second DPD output

Example 19 can include the one or more non-transitory, computer-readable media of example 18, wherein the sequence of instructions that, when executed, further cause the processor circuitry to: determine a target DPD output based on a third DPD output, the third DPD output determined prior to the first DPD output; and determine a loss function based on the target DPD output, wherein the wireless communication is based on the loss function.

Example 20 can include the one or more non-transitory, computer-readable media of any of examples 18 or 19, wherein the sequence of instructions that, when executed, further cause the processor circuitry to: determine a loss function based on the DPD input; and determine a gradient of the loss function, wherein the DPD model is updated based on a self-supervised DPD training algorithm that uses the gradient

Example 21 can include the one or more non-transitory, computer-readable media of any of examples 18-20, wherein updating the DPD model incrementally updates the first DPD output toward a target DPD output.

Example 22 can include the one or more non-transitory, computer-readable media of any of examples 18-21, wherein the sequence of instructions that, when executed, further cause the processor circuitry to: determine that the DPD input is time-aligned with the PA output, wherein the wireless communication is further based on determining that the model input is time-aligned with the PA output

Example 23 can include the one or more non-transitory, computer-readable media of any of examples 18-22, wherein the sequence of instructions that, when executed, further cause the processor circuitry to: convert the first DPD output from a digital signal to an analog signal; and up-convert the analog signal, wherein the wireless communication is further based on up-converting the analog signal.

Example 24 can include a method for performing any of the steps of examples 18-23.

Example 25 can include an apparatus comprising processor circuitry configured to perform any of the steps of example 18-23.

Any of the above-described examples may be combined with any other example (or combination of examples), unless explicitly stated otherwise. The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method for wireless communication comprising:
receiving by at least one processor running a digital predistortion (DPD) model of a transceiver, a DPD input, the transceiver including a power amplifier (PA);
outputting, from the at least one processor and in response to the DPD input, a first DPD output of the DPD model;
causing the PA to generate a PA output based on the first DPD output;
updating the DPD model based on the DPD input, the DPD output and the PA output;
receiving, after the DPD model is updated, the DPD input by the at least one processor;
outputting, by the at least one processor, a second DPD output based on the DPD input; and
causing the wireless communication by the transceiver to a network device based on the second DPD output.

2. The method of claim 1, wherein the method further comprises:
determining a target DPD output based on a third DPD output, the third DPD output determined prior to the first DPD output; and
determining a loss function based on the target DPD output, wherein the wireless communication is based on the loss function.

3. The method of claim 1, wherein the method further comprises:
determining a loss function based on the DPD input; and
determining a gradient of the loss function, wherein the DPD model is updated based on a self-supervised DPD training algorithm that uses the gradient.

4. The method of claim 1, wherein updating the DPD model incrementally updates the first DPD output toward a target DPD output.

5. The method of claim 1, wherein the method further comprises:
determining that the DPD input is time-aligned with the PA output, wherein the wireless communication is further based on determining that the DPD input is time-aligned with the PA output.

6. The method of claim 1, wherein the method further comprises:
converting the first DPD output from a digital signal to an analog signal; and
up-converting the analog signal, wherein the wireless communication is further based on up-converting the analog signal.

7. The method of claim 1, wherein the PA output is a first PA output, and wherein the method further comprises:
converting a second PA output from an analog signal to a digital signal; and
down-converting the digital signal, wherein the first PA output is based on down-converting the digital signal.

8. An apparatus comprising:
processor circuitry configured to:
receive by at least one processor running a digital predistortion (DPD) model of a transceiver, a DPD input, the transceiver including a power amplifier (PA);
output, from the at least one processor and in response to the DPD input, a first DPD output of the DPD model;
cause the PA to generate a PA output based on the first DPD output;
update the DPD model based on the DPD input, the DPD output and the PA output;
receive, after the DPD model is updated, the DPD input by the at least one processor;
output, by the at least one processor, a second DPD output based on the DPD input; and
cause wireless communication by the transceiver to a network device based on the second DPD output.

9. The apparatus of claim 8, wherein the processor circuitry is further configured to:
determine a target DPD output based on a third DPD output, the third DPD output determined prior to the first DPD output; and
determine a loss function based on the target DPD output, wherein the wireless communication is based on the loss function.

10. The apparatus of claim 8, wherein the processor circuitry is further configured to:
determine a loss function based on the DPD input; and
determine a gradient of the loss function, wherein the DPD model is updated based on a self-supervised DPD training algorithm that uses the gradient.

11. The apparatus of claim 8, wherein updating the DPD model incrementally updates the first DPD output toward a target DPD output.

12. The apparatus of claim 8, wherein the processor circuitry is further configured to:
determine that the DPD input is time-aligned with the PA output, wherein the wireless communication is further based on determining that the DPD input is time-aligned with the PA output.

13. The apparatus of claim 8, wherein the processor circuitry is further configured to:
convert the first DPD output from a digital signal to an analog signal; and
up-convert the analog signal, wherein the wireless communication is further based on up-converting the analog signal.

14. The apparatus of claim 8, wherein the PA output is a first PA output, and wherein the processor circuitry is further configured to:
convert a second PA output from an analog signal to a digital signal; and
down-converting the digital signal, wherein the first PA output is based on down-converting the digital signal.

15. One or more non-transitory, computer-readable media comprising a sequence of instructions that, when executed, cause processor circuitry to:
receive by at least one processor running a digital predistortion (DPD) model of a transceiver, a DPD input, the transceiver including a power amplifier (PA);
output, from the at least one processor and in response to the DPD input, a first DPD output of the DPD model;
cause the PA to generate a PA output based on the first DPD output;
update the DPD model based on the DPD input, the DPD output and the PA output;
receive, after the DPD model is updated, the DPD input by the at least one processor;
output, by the at least one processor, a second DPD output based on the DPD input; and
cause wireless communication by the transceiver to a network device based on the second DPD output.

16. The one or more non-transitory, computer-readable media of claim 15, wherein the sequence of instructions that, when executed, further cause the processor circuitry to:
determine a target DPD output based on a third DPD output, the third DPD output determined prior to the first DPD output; and
determine a loss function based on the target DPD output, wherein the wireless communication is based on the loss function.

17. The one or more non-transitory, computer-readable media of claim 15, wherein the sequence of instructions that, when executed, further cause the processor circuitry to:
determine a loss function based on the DPD input; and
determine a gradient of the loss function, wherein the DPD model is updated based on a self-supervised DPD training algorithm that uses the gradient.

18. The one or more non-transitory, computer-readable media of claim 15, wherein updating the DPD model incrementally updates the first DPD output toward a target DPD output.

19. The one or more non-transitory, computer-readable media of claim 15, wherein the sequence of instructions that, when executed, further cause the processor circuitry to:
determine that the DPD input is time-aligned with the PA output, wherein the wireless communication is further based on determining that the model input is time-aligned with the PA output.

20. The one or more non-transitory, computer-readable media of claim 15, wherein the sequence of instructions that, when executed, further cause the processor circuitry to:
convert the first DPD output from a digital signal to an analog signal; and
up-convert the analog signal, wherein the wireless communication is further based on up-converting the analog signal.
